(19) United States
(12) Patent Application Publication
(10) Pub. No.: US 2009/0162797 A1
(43) Pub. Date: Jun. 25, 2009

(54) METHOD OF MANUFACTURING LIQUID EJECTION HEAD

(75) Inventors: Shinsuke Tsuji, Yokohama-shi (JP); Shoji Shiba, Kawasaki-shi (JP); Tamaki Sato, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/334,149

(22) Filed: Dec. 12, 2008

(30) Foreign Application Priority Data
Dec. 19, 2007 (JP) 2007-327406

(51) Int. Cl. G03F 7/20

(52) U.S. Cl. 430/320

(57) ABSTRACT

A method of manufacturing a liquid ejection head includes a step of forming a layer of a positive-type photosensitive resin on a substrate; a step of forming a pattern, used to form a liquid channel, by exposing the positive-type photosensitive resin layer to light; a step of forming a photosensitive layer, used to form a discharge port-forming member, on the pattern; and a step of forming a discharge port in such a manner that the photosensitive layer is patterned by exposing the photosensitive layer to i-line. The pattern has a predetermined absorbance for i-line and contains a specific compound.

### BACKGROUND OF THE INVENTION

1. Field of the Invention

The present invention relates to methods of manufacturing liquid ejection heads discharging liquids and particularly relates to a method of manufacturing a liquid ejection head that ejects ink towards a recording medium to perform recording.

2. Description of the Related Art

Applications of liquid ejection heads that discharge liquids include inkjet-recording systems that eject ink toward recording media to perform recording.

An inkjet-recording head for use in an inkjet-recording system (liquid ejection-recording system) usually includes fine discharge ports, liquid channels, and energy-generating elements which are disposed in portions of the liquid channels and which generate energy used to discharge liquids. A known method of manufacturing such an inkjet-recording head uses photolithography. For example, U.S. Pat. No. 4,657,631 discloses the process below.

A pattern for forming ink channels is formed on a substrate having energy-generating elements using a soluble resin. A resin cover layer, used for forming discharge ports, is formed over the ink channel-forming pattern from a negative-type photosensitive resin material containing an epoxy resin and a cationic photopolymerization initiator. The discharge ports are formed by photolithography. The ink channel-forming pattern, which is made of the soluble resin, is dissolved off. The resin cover layer is finally cured to form walls of the ink channels.

In order to perform high-speed recording and to achieve high-quality images, discharge ports for discharging droplets need to have a reduced diameter and fine channels need to be densely arranged. Known examples of light used to expose negative-type photosensitive resins to be treated by photolithography include light with a broad band and light with a wavelength of 248 nm.

In order to obtain high-definition discharge ports by a process disclosed in U.S. Pat. No. 5,478,606, the inventors have investigated that a negative-type photosensitive resin is patterned in such a manner that the negative-type photosensitive resin is exposed to i-line (365 nm) with a high-precision, high-power stepper. As a result, the problem below has arisen.

Discharge ports with a desired shape were not obtained in some cases depending on the shape of a pattern for forming channels or the surface condition of a substrate. In particular, although an exposure mask having circular portions was used to form discharge ports by patterning, the formed discharge ports had irregular circular shapes, that is, circular discharge ports were not obtained with high reproducibility.

This phenomenon is probably due to the sole use of i-line, which has a wavelength where the transmittance of a negative-type photosensitive resin is high, increases the influence of light reflected by the substrate or the channel-forming pattern. This phenomenon is remarkable when discharge ports have a small diameter and/or channels are densely arranged.

Japanese Patent Laid-Open Nos. 2005-125577 and 2005-125619 each disclose a method of manufacturing an inkjet-recording head using a channel pattern containing an ultraviolet absorber used in a manufacturing process disclosed in U.S. Pat. No. 5,478,606. In this manufacturing method, light used to expose a negative-type photosensitive resin for forming discharge ports is prevented from being reflected by the channel pattern and therefore the amount of scum formed in a portion of an ink channel is reduced.

In the case where i-line is used for exposure in this manufacturing method, the problems below may occur.

The shape of a pattern, formed by irradiating a photosensitive resin only with i-line, for forming discharge ports may not be improved depending on the type or amount of an ultraviolet absorber used. A pattern for forming densely arranged channels may not be obtained as required because of resolution depending on the type or amount of the ultraviolet absorber. The efficiency of a step of removing the channel-forming pattern may be reduced depending on the type or amount of the ultraviolet absorber.

### SUMMARY OF THE INVENTION

The present invention provides a method useful in manufacturing an inkjet-recording head having a fine discharge port which has a desired shape and which is formed by photolithography, including exposure using i-line. Furthermore, the present invention provides a method of manufacturing an inkjet-recording head having an improved discharge port with high reproducibility.

The present invention provides a method of manufacturing a liquid ejection head that includes a substrate including an energy-generating element generating energy used to discharge a liquid from a discharge port and also includes a discharge port-forming member having the discharge port. The method includes forming a layer of a positive-type photosensitive resin, containing a light absorbent, on the substrate; forming a pattern having the same shape as that of a channel by exposing the positive-type photosensitive resin layer to light; forming a photosensitive layer, used to form the discharge port-forming member, over the pattern; forming the discharge port by exposing the photosensitive layer to i-line; and forming the channel by removing the pattern such that the channel is communicatively connected to the discharge port. The absorbance of the pattern measured at a wavelength of 365 nm in the thickness direction thereof is 0.2 or more. At least one of the ratio of the average absorbance of the light absorbent at a wavelength of 230 to 260 nm to the absorbance thereof at a wavelength of 365 nm and the ratio of the average absorbance of the light absorbent at a wavelength of 280 to 330 nm to the absorbance thereof at a wavelength of 365 nm is 1.0 or less.

According to the present invention, a fine discharge port which is present in an inkjet-recording head and which has an extremely improved circular shape can be readily formed with high reproducibility in such a manner that a negative-type photosensitive resin is exposed to i-line.

Further features of the present invention will become apparent from the following description of exemplary embodiments with reference to the attached drawings.

### BRIEF DESCRIPTION OF THE DRAWINGS

FIG. 1 is a schematic plan view of a recording head according to an embodiment of the present invention.

FIG. 2A is a schematic sectional view of the recording head taken along the line II-II of FIG. 1 and FIG. 2B is sectional view of a modification of the recording head.

FIGS. 3A to 3G are schematic sectional views showing steps of a method of manufacturing a recording head according to an embodiment of the present invention.

FIGS. 4A to 4I are schematic sectional views showing steps of a method of manufacturing a recording head according to an embodiment of the present invention.

FIG. 5 is a graph showing the absorption spectrum of a first light absorbent.

FIG. 6 is a graph showing the absorption spectrum of a second light absorbent.

FIG. 7 is a graph showing the absorption spectrum of a third light absorbent.

FIG. 8 is a graph showing the absorption spectrum of a first comparative light absorbent.

FIG. 9 is a graph showing the absorption spectrum of a second comparative light absorbent.

### DESCRIPTION OF THE EMBODIMENTS

Embodiments of the present invention will now be described in detail with reference to the attached drawings.

A liquid ejection head used herein can be mounted in an industrial recording apparatus that includes a device such as a printer, a copier, a facsimile machine including a communication system, or a word processor having a printer section and also includes various processing units. The liquid ejection head can be used to record data on various recording media made of paper, yarn, fiber, fabric, leather, metal, plastic, glass, wood, or ceramic. The term “recording” used herein shall mean storing a meaningful image, such as a text image or a graphic image, on a recording media and also mean storing a meaningless image such as a pattern on a recording media.

The term “ink” or “liquid” used herein should be broadly construed and shall mean a fluid material used to form an image, a figure, a pattern, or the like; used to process a recording medium; or used for the treatment of ink or a recording medium. The term “the treatment of ink or a recording medium” used herein means that a colorant contained in ink applied to a recording medium is coagulated or insolubilized such that fixation, recording quality, color developability, and/or image durability is improved.

An inkjet-recording head (hereinafter referred to as a recording head), which is an application of a liquid ejection head, is described below.

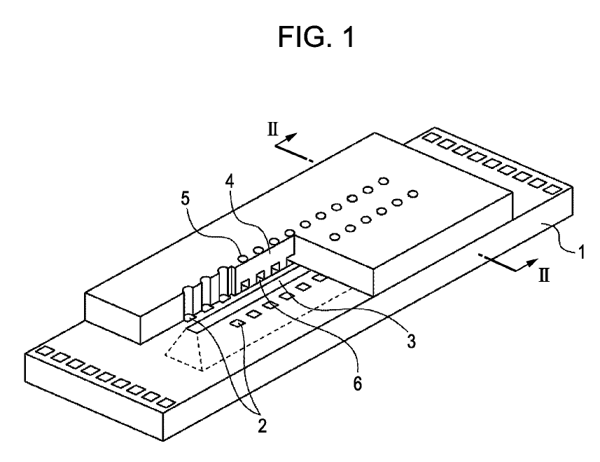

FIG. 1 is a schematic plan view of a recording head according to an embodiment of the present invention.

The recording head includes a substrate 1, made of silicon, including energy-generating elements 2 which generate energy used to discharge a liquid and which are arranged in two lines at a predetermined pitch. The substrate 1 has a supply port 3, formed by anisotropically etching the substrate 1, extending between the two lines of the energy-generating elements 2. The substrate 1 is overlaid with a discharge port-forming member 4 having discharge ports 5 located at positions opposed to the energy-generating elements 2. The discharge port-forming member 4 also has a channel 6 communicatively connecting the supply port 3 to the discharge ports 5 and therefore functions as a channel-forming member. Such a channel-forming member may be used in addition to the discharge port-forming member 4. The positions of the discharge ports 5 are not limited to the positions opposed to the energy-generating elements 2.

The liquid ejection head is placed such that a surface of the liquid ejection head that has the supply port 3 is opposed to a recording surface of a recording medium. The energy generated by the energy-generating elements 2 is applied to ink supplied to the channel 6 through the supply port 3 such that droplets of the ink are discharged from the discharge ports 5, whereby the ink droplets are applied to the recording medium. Examples of the energy-generating elements 2 include, but are not limited to, electrothermal transducers (so-called heaters) for generating thermal energy and piezoelectric transducers for generating mechanical energy.

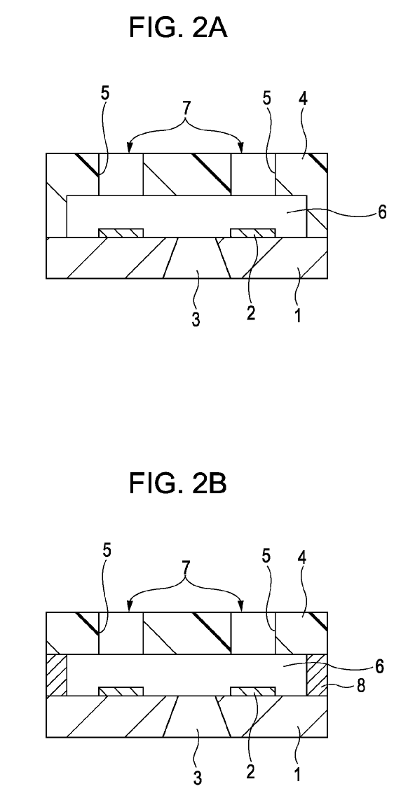

FIG. 2A is a schematic sectional view of the recording head taken along the line II-II of FIG. 1.

With reference to FIG. 2A, the discharge ports 5 correspond to openings arranged in the upper surface of the discharge port-forming member 4 and the discharge port-forming member 4 has discharge portions 7 which communicatively connect the discharge ports 5 to the channel 6 and which are distinguished from the discharge ports 5. The discharge portions 7 may have a tapered shape such that the area of a cross section of each discharge portion 7 that is parallel to the substrate 1, decreases from the substrate 1 toward the discharge ports 5.

As shown in FIG. 2B, a channel-forming member 8 serving as a wall surrounding the channel 6 may be disposed between the discharge port-forming member 4 and the substrate 1.

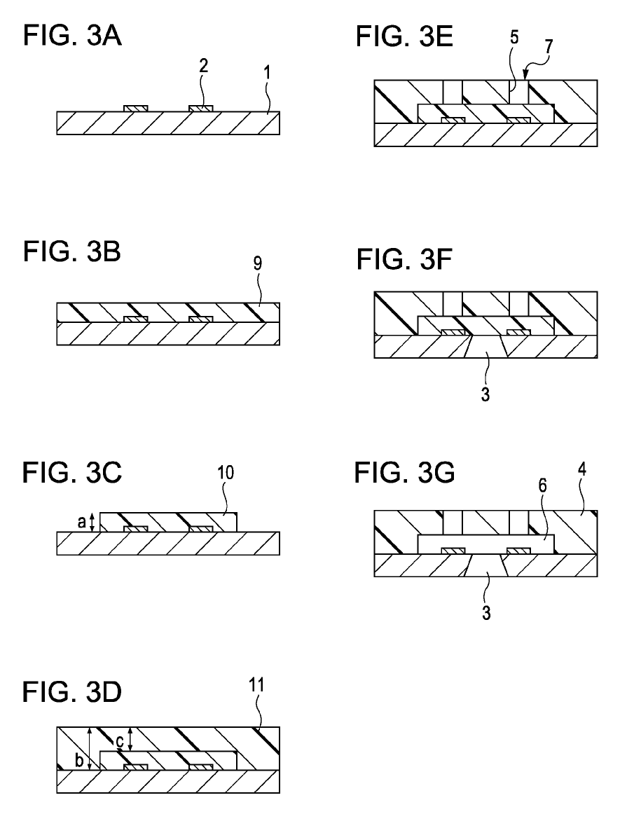

A method of manufacturing a recording head according to an embodiment of the present invention will now be described with reference to FIGS. 3A to 3G.

FIGS. 3A to 3G are schematic sectional views showing steps of the manufacturing method. The sectional view shown in FIG. 3G is substantially identical to that shown in FIG. 2A.

As shown in FIG. 3A, a substrate 1 having energy-generating elements 2 is prepared.

The substrate 1 is used as a member for forming a channel 6. The substrate 1 functions as a support for supporting a discharge port-forming member 4 for forming the channel 6 and discharge ports 5. The shape of the substrate 1 and a material for forming the substrate 1 are not particularly limited. In this embodiment, the substrate 1 is made of silicon because a supply port 3 is formed by anisotropically etching the substrate 1 so as to extend through the substrate 1.

A desired number of the energy-generating elements 2 such as electrothermal transducers or piezoelectric elements are arranged on the substrate 1. The energy-generating elements 2 generate energy used to discharge ink droplets. The energy generated thereby is applied to ink, whereby recording is performed. When the energy-generating elements 2 are, for example, electrothermal transducers, discharge energy is generated in such a manner that the electrothermal transducers heat a recording solution nearby and thereby the recording solution is changed in phase. When the energy-generating elements 2 are, for example, piezoelectric elements, discharge energy is generated by mechanical vibration generated by the piezoelectric elements. The energy-generating elements 2 are connected to control signal input electrodes (not shown) for driving the energy-generating elements 2.

The following layers may be disposed on or above the substrate 1: a protective layer (not shown) for enhancing the durability of the energy-generating elements 2, an adhesion-enhancing layer (not shown) for enhancing the adhesion between the discharge port-forming member 4 and the substrate 1, and a functional layer.

As shown in FIG. 3B, a positive-type photosensitive resin layer 9 is formed over the energy-generating elements 2 and the substrate 1. A common solvent coating process, such as a spin coating process or a slit coating process, can be used to form the positive-type photosensitive resin layer 9.

As shown in FIG. 3C, the positive-type photosensitive resin layer 9 is patterned by photolithography, whereby a pattern 10 for forming an ink channel is formed. The pattern 10 preferably has an overall absorbance of 0.2 or more, more preferably 0.3 or more, and further more preferably 0.4 or more at a wavelength of 365 nm, the overall absorbance being the absorbance through the entire thickness of the pattern 10. When the pattern 10 has an overall absorbance of less than 0.2 at a wavelength of 365 nm, the discharge ports 5 formed through an exposure step below may not have a desired shape. This is probably because when the pattern 10 has a small overall absorbance at a wavelength of 365 nm and 365-nm light is used for pattern exposure for forming the discharge ports 5, portions for forming the discharge ports 5 are exposed to the 365-nm light reflected by the pattern 10 as the pattern 10 does not sufficiently absorb the 365-nm light.

The positive-type photosensitive resin layer 9, which is used to form the pattern 10, is made of a positive-type photosensitive resin. In view of resolution and removal performance, the positive-type photosensitive resin preferably principally contains a photodegradable polymer such as a polymer produced from a compound with a double bond. Preferred examples of the photodegradable polymer include vinyl ketone polymers such as polymethyl isopropenyl ketone and polyvinylketone and acrylic polymers. In view of process resistance, the photodegradable polymer preferably has a number-average molecular weight of 10,000 to 500,000.

In order to adjust the absorbance of the pattern 10, a light absorbent may be added to the positive-type photosensitive resin layer 9 such that the pattern 10 contains the light absorbent. At least one of the ratio of the average absorbance of the light absorbent at a wavelength of 230 to 260 nm to the absorbance thereof at a wavelength of 365 nm and the ratio of the average absorbance of the light absorbent at a wavelength of 280 to 330 nm to the absorbance thereof at a wavelength of 365 nm is preferably 1.0 or less. At least one of these ratios is more preferably 0.7 or less and further more preferably 0.5 or less. The ratio of the average absorbance of the light absorbent at a wavelength of 230 to 260 nm to the absorbance thereof at a wavelength of 365 nm and the ratio of the average absorbance of the light absorbent at a wavelength of 280 to 330 nm to the absorbance thereof at a wavelength of 365 nm can be determined as described below.

The light absorbent is dissolved in a solvent, whereby a solution is prepared. The solution is formed into a film. The film is measured for absorbance at a wavelength of 365 nm, a wavelength of 230 to 260 nm, and a wavelength of 280 to 330 nm. The average absorbance of the film is determined in such a manner that the film is measured for absorbance in increments of, for example, 1 nm within a predetermined wavelength range and the sum of the absorbance measurements obtained at corresponding wavelengths is divided by the number of the wavelengths.

The absorbance of a substance is defined as the product of the absorption coefficient (molar absorption coefficient, when the concentration of the substance is expressed on a molar basis) of the substance, the pathlength of a sample containing the substance, and the concentration of the substance. The thickness of the film and the concentration of the light absorbent in the film do not depend on a measurement wavelength and therefore are constant. The absorbance of the light absorbent is defined by the following equation:

A=ε×b×c

wherein A represents the absorbance of the light absorbent, ε represents the molar absorption coefficient of the light absorbent at a measurement wavelength, b represents the thickness of the film, and c represents the molar concentration of the light absorbent in the film. Therefore, the following equation holds for the light absorbent:

A₂₃₀₋₂₆₀/A₃₆₅=(ε₂₃₀₋₂₆₀×b×c)/(ε₃₆₅×b×c)

wherein A₂₃₀₋₂₆₀ represents the average absorbance of the light absorbent at a wavelength of 230 to 260 nm, A₃₆₅ represents the absorbance of the light absorbent at a wavelength of 365 nm, ε₂₃₀₋₂₆₀ represents the average molar absorption coefficient of the light absorbent at a wavelength of 230 to 260 nm, and ε₃₆₅ represents the molar absorption coefficient of the light absorbent at a wavelength of 365 nm. This equation can be transformed into the following equation:

A₂₃₀₋₂₆₀/A₃₆₅=ε₂₃₀₋₂₆₀/ε₃₆₅

Therefore, the ratio of the absorbance of the average absorbance of the light absorbent at a wavelength of 230 to 260 nm to the absorbance thereof at a wavelength of 365 nm can be rephrased into the ratio of the average molar absorption coefficient of the light absorbent at a wavelength of 230 to 260 nm to the absorbance thereof at a wavelength of 365 nm. The ratio of the average absorbance of the light absorbent at a wavelength of 280 to 330 nm to the absorbance thereof at a wavelength of 365 nm can also be rephrased into the ratio of the average molar absorption coefficient of the light absorbent at a wavelength of 230 to 260 nm to the absorbance thereof absorbent at a wavelength of 365 nm.

The average molar absorption coefficient of a substance is determined in such a manner that the substance is measured for molar absorption coefficient in increments of, for example, 1 nm within a predetermined wavelength range and the sum of the molar absorption coefficients obtained at corresponding wavelengths is divided by the number of the wavelengths.

If a known light absorbent in which at least one of the above ratios is greater than 1.0 is used to form the pattern 10, the formed pattern 10 strongly absorbs light with a wavelength of 230 to 260 nm or a wavelength of 280 to 330 nm. If a vinylketone or acrylic photodegradable polymer, strongly absorbing light with a wavelength of 230 to 260 nm or a wavelength of 280 to 330 nm, is used to form the pattern 10, the sensitivity and resolution of a solid layer are reduced. Therefore, the pattern 10 may not be formed so as to have a desired shape. The reason for this phenomenon is probably as described below. The vinylketone or acrylic photodegradable polymer, which is usable to form the pattern 10, is degraded by light with a wavelength of 230 to 260 nm or a wavelength of 280 to 330 nm. However, the known light absorbent strongly absorbs light with a wavelength of 230 to 260 nm or a wavelength of 280 to 330 nm and therefore the photodegradation of the pattern 10 is prevented.

The light absorbent used herein is not particularly limited and may be any compound that meets the requirement that at least one of the above ratios is 1.0 or less. Examples of the light absorbent include bisazides having the following formula:

RN₃)ₙ (I)

wherein R represents an n-valent organic group and n represents an integer of one or more.

Particular examples of the light absorbent include compounds having the following formulas:

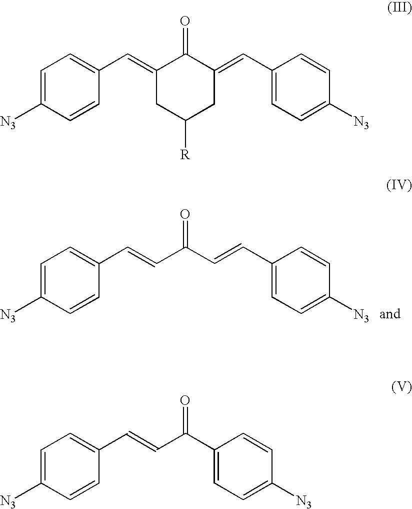

wherein R represents a hydrogen atom or an alkyl group.

Other examples of the light absorbent include triazines having the following formula:

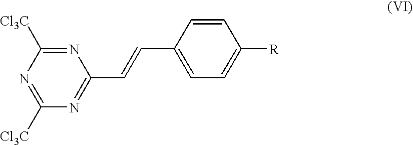

wherein R represents an alkyl or alkoxy group.

Furthermore, other examples of the light absorbent include polynuclear aromatics having the following formula:

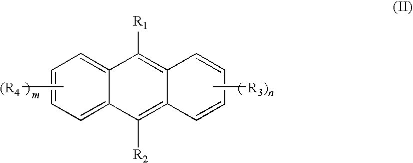

wherein R1, R2, R3, and R4 independently represent a hydrogen atom or a monovalent organic group and n and m independently represent an integer of zero to four.

The light absorbent is not limited to a single compound and may be a mixture of different compounds or a resin composition. The light absorbent may be a resin composition, such as SWK-T7 LE available from Tokyo Ohka Kogyo Co., Ltd., used to form antireflective coatings for semiconductor devices. The pattern 10 preferably contains at least one of those compounds so as to have an overall absorbance of 0.2 or more at a wavelength of 365 nm.

The pattern 10 includes a single layer of the positive-type photosensitive resin and may have a multilayer structure including two or more different layers.

The wavelength of light used to expose the positive-type photosensitive resin layer 9, which is processed into the pattern 10, is not particularly limited. In view of the accuracy and sensitivity of the positive-type photosensitive resin layer 9, a light source with high irradiation intensity at a wavelength of 230 to 330 nm is preferably used to expose the positive-type photosensitive resin layer 9.

As shown in FIG. 3D, a negative-type photosensitive resin layer 11 to be processed into the discharge port-forming member 4 is formed over the pattern 10 and the substrate 1 by a spin coating process, a roll coating process, a slit coating process, or another process. The negative-type photosensitive resin layer 11 is used as a member for forming the ceiling and/or a portion of the channel 6. Therefore, the negative-type photosensitive resin layer 11 needs to have high mechanical strength, high adhesion to the substrate 1, high ink resistance, and high resolution for forming a fine pattern for forming ink discharge ports. A preferred material that meets these requirements is a cationically polymerizable epoxy resin composition.

Examples of an epoxy resin contained in the epoxy resin composition include, but are not limited to, a product which results from the reaction of bisphenol-A with epichlorohydrin and which has a molecular weight of about 900 or more, a product resulting from the reaction of bromine-containing bisphenol-A with epichlorohydrin, a product resulting from the reaction of a phenol novolac or o-cresol novolac resin with epichlorohydrin, and multifunctional epoxy resins which have an oxycyclohexane skeleton and which are disclosed in Japanese Patent Laid-Open Nos. 60-161973, 63-221121, 64-9216, and 2-140219. The epoxy resin preferably has an epoxy equivalent of 2,000 or less and more preferably 1,000 or less. This is because when the epoxy equivalent of the epoxy resin is greater than 2,000, the cured epoxy resin has a reduced crosslink density and therefore is problematic in adhesion and/or ink resistance.

The epoxy resin composition may contain a cationic polarization initiator, such as a compound which produces an acid by light irradiation, for curing the epoxy resin. Examples of such a compound include, but are not limited to, aromatic sulfonium salts and aromatic iodonium salts. Examples of the aromatic sulfonium salts include TPS-102, TPS-103, TPS-105, MDS-103, MDS-105, MDS-205, MDS-305, DTS-102, and DTS-103 commercially available from Midori Kagaku Co., Ltd. and also include SP-170 and SP-172 commercially available from Asahi Denka Co., Ltd. Examples of the aromatic iodonium salts include DPI-105, MPI-103, MPI-105, BBI-101, BBI-102, BBI-103, and BBI-105. The amount of the cationic polarization initiator used may be arbitrarily set such that target sensitivity can be obtained. The amount of the cationic polarization initiator used is preferably 0.5% to 5% by weight of the epoxy resin. The epoxy resin composition may contain a wavelength sensitizer such as SP-100 commercially available from Asahi Denka Co., Ltd. as required.

The epoxy resin composition may further contain an additive such as a flexibilizer for reducing the elastic modulus of the epoxy resin or a silane coupling agent for enhancing the adhesion to the substrate 1.

As shown in FIG. 3E, the pattern 10 is exposed through a mask (not shown) and then developed, whereby the discharge ports 5 and discharge portions 7 are formed. The pattern 10 may be dissolved off during development. In this step, i-line is used to expose the pattern 10. It is known that i-line has a center wavelength of 365 nm and has a half-width of about 5 nm. A commercially available i-line stepper may be used to expose the pattern 10.

As shown in FIG. 3F, the supply port 3 is formed so as to extend through the substrate 1. The supply port 3 may be formed in such a manner that the substrate 1 is anisotropically etched through an etching mask, made from a resin composition, resistant an etching solution.

As shown in FIG. 3G, the pattern 10 is removed, whereby the channel 6 is formed. An ink supply member (not shown) is bonded to the substrate 1 by heat treatment and electric junctions (not shown) for driving the energy-generating elements 2, are formed as required, whereby the recording head is completed.

The manufacturing method is useful in manufacturing an inkjet-recording head having an ink channel and ink discharge ports precisely formed.

### EXAMPLES

The present invention is further described below in detail with reference to examples.

### Preparation of Resin Compositions for Forming Patterns for Channels

Resin compositions for forming patterns 10 for channels were prepared. The resin compositions are summarized in Table 1. The amounts of components shown in Table 1 are expressed in parts by weight.

TABLE 1

| | Base resins | Light absorbents |
|---|---|---|
| First resin | Polymethyl | First light |
| composition | isopropenyl ketone*¹ | absorbent |
| | 100 parts | 0.29 parts |
| Second resin | Polymethyl | First light |
| composition | isopropenyl ketone*¹ | absorbent |
| | 100 parts | 0.14 parts |
| Third resin | Copolymer*² | Second light |
| composition | | absorbent |
| | 100 parts | 0.28 parts |
| Fourth resin | Copolymer*² | Third light |
| composition | | absorbent |
| | 100 parts | 33.3 parts |
| First comparative | Polymethyl | First comparative |
| resin composition | isopropenyl ketone*¹ | light absorbent |
| | 100 parts | 26.6 parts |
| Second | Copolymer*² | Second comparative |
| comparative resin | | light absorbent |
| composition | 100 parts | 15.8 parts |
| Third comparative | Polymethyl | First light |
| resin composition | isopropenyl ketone*¹ | absorbent |
| | 100 parts | 0.07 parts |

*¹ODUR available from Tokyo Ohka Kogyo Co., Ltd.
*²A copolymer prepared from methacrylic acid and methyl methacrylate in a ratio of 10:9. A 20-weight percent diglyme solution of the copolymer was used.

Table 2 shows the absorbance ratios of light absorbents used.

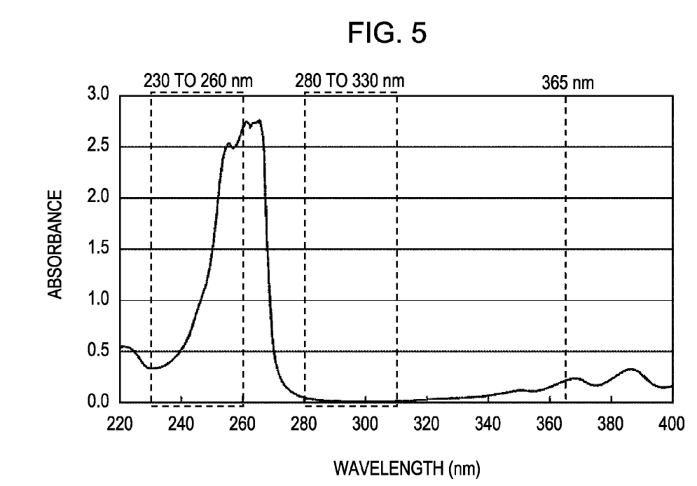

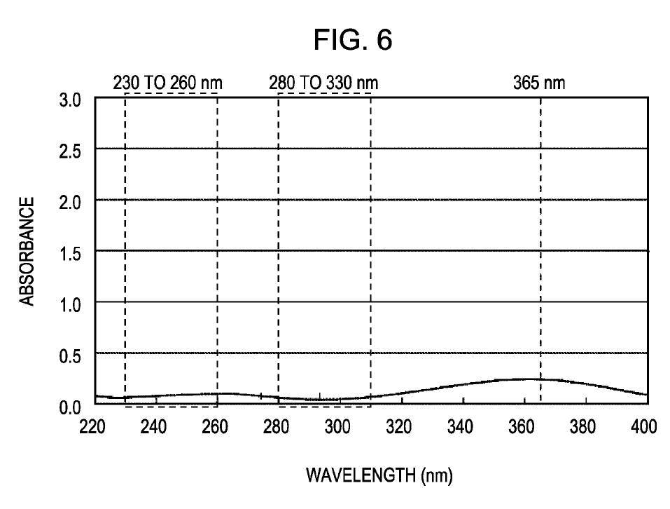

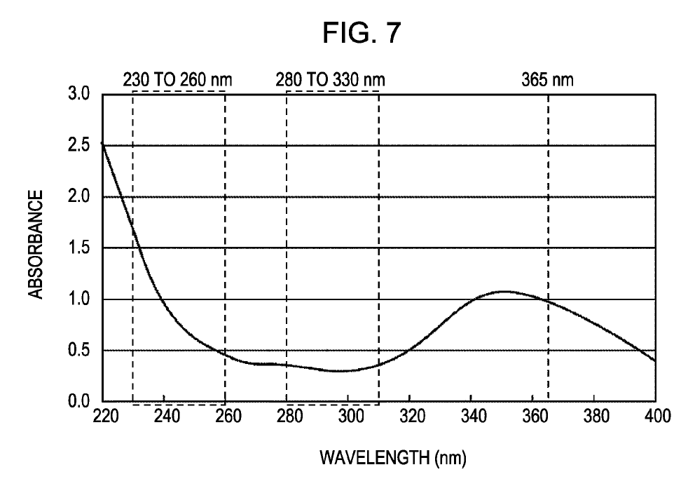

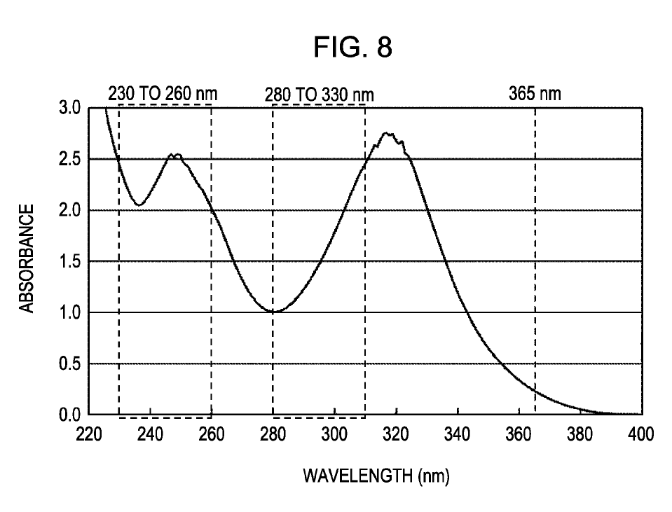

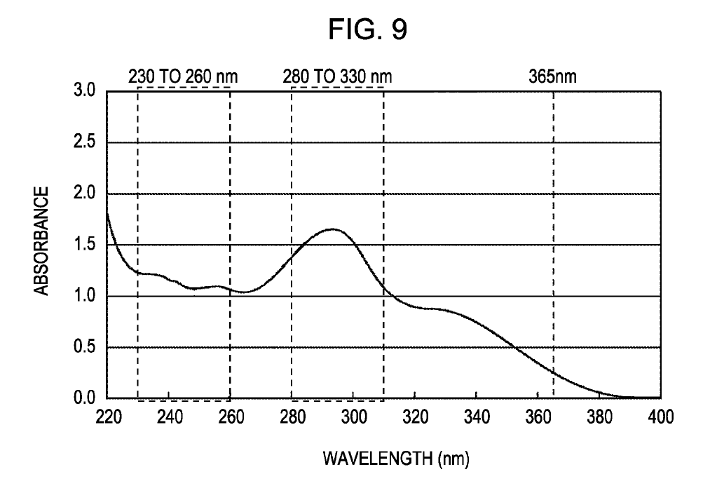

FIGS. 5, 6, 7, 8, and 9 show the ultraviolet absorption spectrum of a first light absorbent, that of a second light absorbent, that of a third light absorbent, that of a first comparative light absorbent, and that of a second comparative light absorbent, respectively.

The ultraviolet absorption spectrum of each light absorbent was determined in such a manner that a solution prepared by dissolving the light absorbent in a solvent was formed into a film and the ultraviolet absorption spectrum of a reference was subtracted from that of the film. The absorbance ratios shown in Table 2 are defined as below.

First absorbance ratio: the ratio of the average absorbance of each light absorbent at a wavelength of 230 to 260 nm to the absorbance thereof at a wavelength of 365 nm

Second absorbance ratio: the ratio of the average absorbance of the light absorbent at a wavelength of 280 to 330 nm to the absorbance thereof at a wavelength of 365 nm

The absorbance of each light absorbent was determined in such a manner that a solution prepared by dissolving the light absorbent in a solvent was formed into a film and the absorbance of a reference was subtracted from that of the film. The average absorbance of the light absorbent was determined in such a manner that the film was measured for absorbance in increments of 1 nm within a wavelength range from 230 to 260 nm or a wavelength range from 280 to 330 nm and the sum of the absorbance measurements obtained at corresponding wavelengths was divided by the number of the wavelengths.

TABLE 2

| | | First | Second |
|---|---|---|---|
| | | absorbance | absorbance |
| | Materials | ratio | ratio |
| First light | 9,10- | 5.53 | 0.12 |
| absorbent | diethoxyanthracene*¹ | | |
| Second light | 2,6-di(p- | 0.36 | 0.29 |
| absorbent | azidobenzal)-4- | | |
| | methylcyclohexanone*² | | |
| Third light | Semiconductor | 0.76 | 0.26 |
| absorbent | antireflective | | |
| | coating material*³ | | |
| First | Benzophenone | 9.99 | 8.47 |
| comparative | compound*⁴ | | |
| light | | | |
| absorbent | | | |
| Second | 3-benzoyl coumarin*⁵ | 4.58 | 5.06 |
| comparative | | | |
| light | | | |
| absorbent | | | |

*¹SP-100 available from Asahi Denka Co., Ltd.
*²BAC-M available from Toyo Gosei Co., Ltd.
*³SWK-T7 LE available from Tokyo Ohka Kogyo Co., Ltd.
*⁴KAYACURE BMS available from Nippon Kayaku Co., Ltd.
*⁵3-benzoylcoumarin was synthesized with reference to Tetrahedron, Vol. 38, No. 9, 1203 (1982).

The first light absorbent has Formula II in which R1 and R2 each represent a group having the formula OCH₂CH₃ and R3 and R4 each represent a hydrogen atom. The second light absorbent has Formula III in which R represents a methyl group.

### Preparation of Negative-Type Photosensitive Resin for Forming Discharge Port-Forming Member

A negative-type photosensitive resin composition A for forming a discharge port-forming member was prepared from materials below.

(1) 100 parts by weight of an epoxy resin, EHPE-3150, available from Daicel Chemical Industries Ltd.

(2) Two parts by weight of a cationic photopolymerization initiator, SP-172, available from Asahi Denka Co., Ltd.

(3) 100 parts by weight of methyl isobutyl ketone

### Example 1

An inkjet-recording head substantially identical to that shown in FIG. 2A was prepared by the manufacturing method described above with reference to FIGS. 3A to 3G.

As shown in FIG. 3A, a substrate 1, made of silicon, having the following components was prepared: electrothermal transducers (heaters made of HfB₂) serving as energy-generating elements 2 and a multilayer film (not shown), including a silicon nitride layer and a tantalum layer, for forming an ink channel.

As shown in FIG. 3B, a layer of a solution prepared by dissolving a first resin composition shown in Table 1 in a solvent was formed on the substrate 1 by spin coating and then baked at 150° C. for three minutes, whereby a positive-type photosensitive resin layer 9 was formed. The positive-type photosensitive resin layer 9 disposed on the substrate 1 had a thickness of 10 μm.

As shown in FIG. 3C, the positive-type photosensitive resin layer 9 was patterned in such a manner that the positive-type photosensitive resin layer 9 was exposed with a dose of 30,000 mJ/cm² using a deep UV exposure system, UX-3000, available from Ushio Inc.; developed with methyl isobutyl ketone; and then rinsed with isopropyl alcohol, whereby a pattern 10 with a thickness of 10 μm was formed, the thickness thereof being represented by a in FIG. 3C.

As shown in FIG. 3D, the negative-type photosensitive resin composition A was spin-coated over the pattern 10 and the substrate 1, whereby a negative-type photosensitive resin layer 11 for forming a discharge port-forming member was formed. The negative-type photosensitive resin layer 11 had a first portion, disposed on the substrate 1, having a thickness of 20 μm and a second portion, disposed on the pattern 10, having a thickness of 10 μm, the thickness of the first portion and that of the second portion being represented by b and c, respectively, in FIG. 3C.

As shown in FIG. 3E, the negative-type photosensitive resin layer 11 was patterned in such a manner that the negative-type photosensitive resin layer 11 was exposed with a dose of 5,000 mJ/cm² using an i-line stepper, FPA-3000i5+, available from CANON KABUSHIKI KAISHA; developed with methyl isobutyl ketone; rinsed with isopropyl alcohol; and then heat-treated at 100° C. for 60 minutes, whereby discharge portions 7 having corresponding discharge ports 5 were formed. In this example, a discharge port pattern mask having a circular shape was used for exposure. The pattern 10 was not damaged by exposure or development for forming the discharge ports 5 and remained unchanged in shape.

As shown in FIG. 3F, an etching mask (not shown) was formed on the rear surface of the substrate 1, a protective layer (not shown) for protecting the negative-type photosensitive resin layer 11 from an etching solution was formed on the negative-type photosensitive resin layer 11 using OBC available from Tokyo Ohka Kogyo Co., Ltd., and the substrate 1 was then anisotropically etched through the etching mask, whereby a supply port 3 for supplying ink was formed.

After the protective layer was dissolved off with xylene, the pattern 10 was exposed with a dose of 250,000 mJ/cm² through the negative-type photosensitive resin layer 11 using a deep UV exposure system, UX-3000, available from Ushio Inc., whereby the pattern 10 was solubilized. The resulting pattern 10 was immersed in methyl lactate and applied with ultrasonic waves, whereby the pattern 10 was dissolved off as shown in FIG. 3G.

The inkjet-recording head was obtained as described above.

### Example 2

An inkjet-recording head was prepared in substantially the same manner as that described in Example 1 except that a second resin composition shown in Table 1 was used to form a positive-type photosensitive resin layer 9 for forming a pattern 10.

### Comparative Example 1

An inkjet-recording head was prepared in substantially the same manner as that described in Example 1 except that polymethyl isopropenyl ketone, ODUR, available from Tokyo Ohka Kogyo Co., Ltd. was used to form a positive-type photosensitive resin layer 9 for forming pattern 10 without any light absorbent.

### Comparative Example 2

An inkjet-recording head was prepared in substantially the same manner as that described in Example 1 except that a first comparative resin composition shown in Table 1 was used to form a positive-type photosensitive resin layer 9 for forming a pattern 10.

### Comparative Example 6

An inkjet-recording head was prepared in substantially the same manner as that described in Example 1 except that a third comparative resin composition shown in Table 1 was used to form a positive-type photosensitive resin layer 9 for forming a pattern 10.

### Example 3

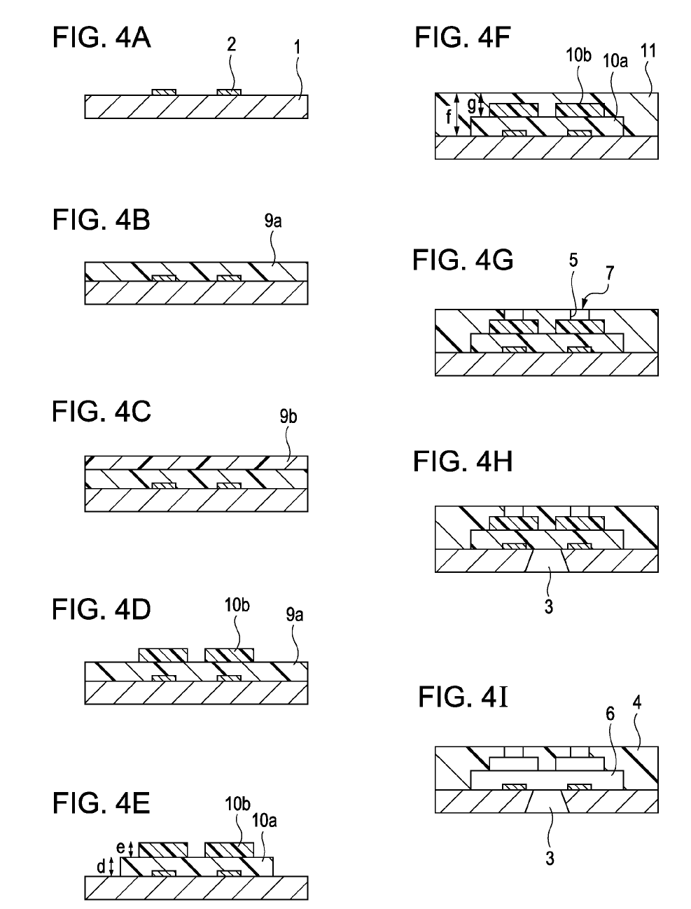

Example 3 of the present invention is described below with reference to FIGS. 4A to 4I.

As shown in FIG. 4A, a substrate 1 substantially identical to that used in Example 1 was prepared.

A layer of polymethyl isopropenyl ketone, ODUR, available from Tokyo Ohka Kogyo Co., Ltd. was formed on the substrate 1 by spin coating and then baked at 150° C. for three minutes, whereby a first positive-type photosensitive resin layer 9a was formed.

As shown in FIG. 4C, a layer of a solution prepared by dissolving a third resin composition shown in Table 1 in a solvent was formed on the substrate 1 by spin coating and then baked at 150° C. for three minutes, whereby a second positive-type photosensitive resin layer 9b was formed. The first positive-type photosensitive resin layer 9a had a thickness of 10 μm and the second positive-type photosensitive resin layer 9b had a thickness of 5 μm.

As shown in FIG. 4D, the second positive-type photosensitive resin layer 9b was patterned in such a manner that the second positive-type photosensitive resin layer 9b was exposed with a dose of 10,000 mJ/cm² using a deep UV exposure system, UX-3000, available from Ushio Inc., the system being equipped with a filter for filtering out light with a wavelength of 260 nm or more; developed with methyl isobutyl ketone; and then rinsed with isopropyl alcohol, whereby a second pattern 10b was formed.

As shown in FIG. 4E, the first positive-type photosensitive resin layer 9a was patterned in such a manner that the first positive-type photosensitive resin layer 9a was exposed with a dose of 30,000 mJ/cm² using the deep UV exposure system, UX-3000, equipped with a filter for filtering out light with a wavelength of less than 260 nm; developed with methyl isobutyl ketone; and then rinsed with isopropyl alcohol, whereby a first pattern 10a was formed. The first pattern 10a had a thickness of 10 μm, the thickness thereof being represented by d in FIG. 4E. The second pattern 10b had a thickness of 5 μm, the thickness thereof being represented by e in FIG. 4E.

As shown in FIG. 4F, the negative-type photosensitive resin composition A was spin-coated over the first and second patterns 10a and 10b and the substrate 1 by spin coating, whereby a negative-type photosensitive resin layer 11 was formed. The negative-type photosensitive resin layer 11 had a first portion, disposed on the substrate 1, having a thickness of 25 μm and a second portion, disposed on the first pattern 10a, having a thickness of 10 μm, the thickness of the first portion and that of the second portion being represented by f and g, respectively, in FIG. 4F.

Discharge ports 5 were formed as described below. The negative-type photosensitive resin layer 11 was exposed with a dose of 5,000 mJ/cm² using an i-line stepper, FPA-3000i5+, available from CANON KABUSHIKI KAISHA; developed with methyl isobutyl ketone; rinsed with isopropyl alcohol; and then heat-treated at 100° C. for 60 minutes, whereby a discharge port-forming member 4 having discharge portions 7 having the corresponding discharge ports 5 were formed as shown in FIG. 4G. In this example, a discharge port pattern mask having a circular shape was used for exposure. The pattern 10 was not damaged by exposure or development for forming the discharge ports 5 and remained unchanged in shape.

As shown in FIG. 4H, a supply port 3 was formed in the same manner as that described in Example 1.

The first and second patterns 10a and 10b were exposed with a dose of 250,000 mJ/cm² through the negative-type photosensitive resin layer 11 using a deep UV exposure system, UX-3000, available from Ushio Inc., whereby the first and second patterns 10a and 10b were solubilized. The resulting first and second patterns 10a and 10b were immersed in methyl lactate and applied with ultrasonic waves, whereby the first and second patterns 10a and 10b were dissolved off as shown in FIG. 4I.

The inkjet-recording head was obtained as described above.

### Example 4

An inkjet-recording head was prepared in substantially the same manner as that described in Example 3 except that a fourth resin composition shown in Table 1 was used to form a second positive-type photosensitive resin layer 9b for forming a second pattern 10b.

### Example 5

An inkjet-recording head was prepared in substantially the same manner as that described in Example 3 except that a second resin composition shown in Table 1 was used to form a first positive-type photosensitive resin layer 9a for forming a first pattern 10a and a copolymer shown in Table 1 was used to form a second positive-type photosensitive resin layer 9b for forming a second pattern 10b.

### Example 6

An inkjet-recording head was prepared in substantially the same manner as that described in Example 3 except that a second resin composition shown in Table 1 was used to form a first positive-type photosensitive resin layer 9a for forming a first pattern 10a and a fourth resin composition shown in Table 1 was used to form a second positive-type photosensitive resin layer 9b for forming a second pattern 10b.

### Comparative Example 3

An inkjet-recording head was prepared in substantially the same manner as that described in Example 3 except that a copolymer shown in Table 1 was used to form a second positive-type photosensitive resin layer 9b for forming a second pattern 10b.

### Comparative Example 4

An inkjet-recording head was prepared in substantially the same manner as that described in Example 3 except that a second comparative resin composition shown in Table 1 was used to form a second positive-type photosensitive resin layer 9b for forming a second pattern 10b.

### Comparative Example 5

An inkjet-recording head was prepared in substantially the same manner as that described in Example 3 except that a first comparative resin composition shown in Table 1 was used to form a first positive-type photosensitive resin layer 9a for forming a first pattern 10a and a copolymer shown in Table 1 was used to form a second positive-type photosensitive resin layer 9b for forming a second pattern 10b.

The inkjet-recording heads prepared as described above were evaluated for characteristics. The evaluation results and evaluation methods were as described below.

### Shape of Discharge Ports

The discharge ports of each inkjet-recording head were observed for shape with a scanning electron microscope.

The discharge ports were then evaluated in such a manner that the shape of each discharge port was compared with that of the mask, which was circular, used to form the discharge port. Evaluation standards were as described below.

A: Discharge ports that had substantially the same shape as that of masks used to form these discharge ports and were substantially circular

B: Discharge ports that were different in shape from masks used to form these discharge ports and had a substantially irregular circular shape Reproducibility of shape of discharge ports

Five hundred inkjet-recording heads were prepared in the same manner as that of each example or comparative example. Ten discharge ports of each inkjet-recording head were checked whether there were differences in shape between the discharge ports of the inkjet-recording heads. Evaluation standards were as described below.

A: Five hundred inkjet-recording heads in which all discharge ports had the same shape

B: Five hundred inkjet-recording heads in which 20% or less of discharge ports had a shape different from that of the other discharge ports

C: Five hundred inkjet-recording heads in which greater than 20% of discharge ports had a shape different from that the other discharge ports Shape accuracy of channel patterns

In the course of preparing the inkjet-recording head of each example or comparative example, the substrate (shown in FIG. 3C or 4E) carrying the pattern for forming the channel was observed with an optical microscope and a scanning electron microscope and the pattern was evaluated. Evaluation standards were as described below.

A: A substrate which had no residue and carried a clear pattern

B: A substrate having residues present on a portion thereof

C: A substrate having residues present thereover

### Removability of Channel Patterns

In the course of preparing the inkjet-recording head of each example or comparative example, after the pattern was removed from the substrate, the substrate (shown in FIG. 3G or 4I) was observed with an optical microscope and a scanning electron microscope and checked whether pieces of the pattern remained. Evaluation standards were as described below.

A: A substrate which had no piece of a pattern and carried a clear ink channel

B: A substrate having pieces of a pattern that were present on a portion thereof

C: A substrate having pieces of a pattern that were present thereover

### Reliability Test

Ink containing the following components was prepared: 79.4 parts by weight of pure water, 15 parts by weight of diethylene glycol, three parts by weight of isopropyl alcohol, 0.1 parts by weight of lithium acetate, and 2.5 parts by weight of a black dye (Food Black 2). After the inkjet-recording head of each example or comparative example was immersed in the ink at 60° C. for three months, the adhesion between the discharge port-forming member 4 and the substrate 1 was evaluated. Evaluation standards were as described below.

A: An inkjet-recording head in which a discharge port-forming member 4 was not at all separated from a substrate 1

B: An inkjet-recording head in which a discharge port-forming member 4 was separated from a substrate 1 in less than 50% of the area of the inkjet-recording head

C: An inkjet-recording head in which a discharge port-forming member 4 was separated from a substrate 1 in 50% or more of the area of the inkjet-recording head

### Evaluation Results

The evaluation results of the inkjet-recording heads of the examples and comparative examples are shown in Table 3.

TABLE 3

| | Channel patterns | |
|---|---|---|
| | First patterns | Second patterns |
| Example 1 | First resin composition | |
| Example 2 | Second resin composition | |
| Example 3 | Polymethyl isopropenyl | Third resin composition |
| | ketone | |
| Example 4 | Polymethyl isopropenyl | Fourth resin |
| | ketone | composition |
| Example 5 | Second resin | Copolymer*¹ |
| | composition | |
| Example 6 | Second resin | Fourth resin |
| | composition | composition |
| Comparative | Polymethyl isopropenyl ketone | |
| Example 1 | | |
| Comparative | First comparative resin composition | |
| Example 2 | | |
| Comparative | Polymethyl isopropenyl | Copolymer* |
| Example 3 | ketone | |
| Comparative | Polymethyl isopropenyl | Second comparative |
| Example 4 | ketone | resin composition |
| Comparative | First comparative | Copolymer* |
| Example 5 | resin composition | |

| Comparative | Third comparative resin composition | | |
|---|---|---|---|
| Example 6 | | | |
| | Overall | | |
| | absorbance*² of | | Reproducibility |
| | channel | Shape of | of shape of |
| | patterns | discharge ports | discharge ports |
| Example 1 | 0.4 | A | A |
| Example 2 | 0.2 | A | A |
| Example 3 | 0.8 | A | A |
| Example 4 | 1.0 | A | A |
| Example 5 | 0.2 | A | A |
| Example 6 | 1.0 | A | A |
| Comparative | 0.0 | B | C |
| Example 1 | | | |
| Comparative | 0.6 | A | A |
| Example 2 | | | |
| Comparative | 0.0 | B | C |
| Example 3 | | | |
| Comparative | 0.6 | A | A |
| Example 4 | | | |
| Comparative | 0.6 | A | A |
| Example 5 | | | |
| Comparative | 0.1 | B | C |
| Example 6 | | | |

| | Shape accuracy | Removability of | |
|---|---|---|---|
| | of channel | channel | Reliability |
| | patterns | patterns | of heads |
| Example 1 | A | A | A |
| Example 2 | A | A | A |
| Example 3 | A | A | A |
| Example 4 | A | A | A |
| Example 5 | A | A | A |
| Example 6 | A | A | A |
| Comparative | A | A | A |
| Example 1 | | | |
| Comparative | C | C | B |
| Example 2 | | | |
| Comparative | A | A | A |
| Example 3 | | | |
| Comparative | C | C | B |
| Example 4 | | | |
| Comparative | C | C | B |
| Example 5 | | | |
| Comparative | A | A | A |
| Example 6 | | | |

*¹A copolymer prepared from methacrylic acid and methyl methacrylate in a ratio of 10:90. The copolymer was used in the form of a 20-weight percent diglyme solution.
*²The overall absorbance in this table is the absorbance through the entire thickness of each solid layer measured at a wavelength of 365 nm.

Each of the inkjet-recording heads of Examples 1 to 6 was attached to a recording system, which was used for recording using ink containing 79.4 parts by weight of pure water, 15 parts by weight of diethylene glycol, three parts by weight of isopropyl alcohol, 0.1 parts by weight of lithium acetate, and 2.5 parts by weight of a black dye (Food Black 2). The ink was precisely discharged from the recording system and high-quality prints were obtained.

In the inkjet-recording heads of Examples 1 to 6, the discharge ports were improved in shape. This is probably because the patterns of the inkjet-recording heads of Examples 1 to 6 have an overall absorbance of 0.2 or more and therefore are effective in preventing irradiation light used to form the discharge ports from being reflected by the substrates in contrast to the patterns of the inkjet-recording heads of Comparative Examples 1, 3, and 6, in which the discharge ports were not improved in shape. In the inkjet-recording heads of Examples 1 to 6, the channel patterns were the desired in shape accuracy. In the inkjet-recording heads of Comparative Examples 2, 4, and 6, residues remained after development. This is probably because the positive-type photosensitive resins used to form the channel patterns of Examples 1 to 6 contained the light absorbents having at least one of a first absorbance ratio (defined as above) of 1.0 or less and a second absorbance ratio (defined as above) of 1.0 or less and therefore the influence of patterning on the positive-type photosensitive resins was slight.

While the present invention has been described with reference to exemplary embodiments, it is to be understood that the invention is not limited to the disclosed exemplary embodiments. The scope of the following claims is to be accorded the broadest interpretation so as to encompass all modifications and equivalent structures and functions.

This application claims the benefit of Japanese Application No. 2007-327406 filed Dec. 19, 2007, which is hereby incorporated by reference herein in its entirety.

What is claimed is:

1. A method of manufacturing a liquid ejection head that includes a substrate including an energy-generating element generating energy used to discharge a liquid from a discharge port and also includes a discharge port-forming member having the discharge port, the method comprising the steps of:
forming a layer of a positive-type photosensitive resin containing a light absorbent on the substrate;
forming a pattern having the same shape as that of a channel by exposing the positive-type photosensitive resin layer;
forming a photosensitive layer, used to form the discharge port-forming member, over the pattern;
forming the discharge port by exposing the photosensitive layer to i-line; and
forming the channel by removing the pattern such that the channel is communicatively connected to the discharge port,
wherein the absorbance of the pattern measured at a wavelength of 365 nm in the thickness direction thereof is 0.2 or more and at least one of the ratio of the average absorbance of the light absorbent at a wavelength of 230 to 260 nm to the absorbance thereof at a wavelength of 365 nm and the ratio of the average absorbance of the light absorbent at a wavelength of 280 to 330 nm to the absorbance thereof at a wavelength of 365 nm is 1.0 or less.

2. The method according to claim 1, wherein the positive-type photosensitive resin is patterned in such a manner that the positive-type photosensitive resin is exposed to light with a wavelength of 230 to 330 nm.

3. The method according to claim 1, wherein the light absorbent contains a compound represented by the following formula:
RN₃)ₙ (I)
wherein R represents an n-valent organic group and n represents an integer of one or more.

4. The method according to claim 1, wherein the light absorbent contains a compound represented by the following formula: 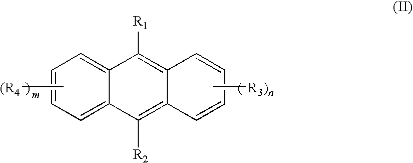
wherein R1, R2, R3, and R4 independently represent a hydrogen atom or a monovalent organic group and n and m independently represent an integer of zero to four.

5. The method according to claim 1, wherein the positive-type photosensitive resin contains a polymer, obtained from a compound with a double bond, having a number-average molecular weight of 10,000 to 500,000 and the step of forming the photosensitive layer on the substrate includes a substep of providing the pattern, which has the same shape as that of the channel communicatively connected to the discharge port, on the substrate and a substep of forming the photosensitive layer over the pattern and the substrate.

6. The method according to claim 1, wherein the positive-type photosensitive resin is polymethyl isopropenyl ketone.

7. A method of manufacturing a liquid ejection head that includes a substrate including an energy-generating element generating energy used to discharge a liquid from a discharge port and also includes a discharge port-forming member having the discharge port, the method comprising the steps of:
forming a layer of a positive-type photosensitive resin containing a compound on the substrate;
forming a pattern having the same shape as that of a channel by exposing the positive-type photosensitive resin layer;
forming a photosensitive layer, used to form the discharge port-forming member, over the pattern;
forming the discharge port by exposing the photosensitive layer to i-line; and
forming the channel, communicatively connected to the discharge port, by removing the pattern,
wherein the absorbance of the pattern measured at a wavelength of 365 nm in the thickness direction thereof is 0.2 or more and the compound is represented by the following formula:
RN₃)ₙ (I)
where R represents an n-valent organic group and n represents an integer of one or more.

8. A method of manufacturing a liquid ejection head that includes a substrate including an energy-generating element generating energy used to discharge a liquid from a discharge port and also includes a discharge port-forming member having the discharge port, the method comprising the steps of:
forming a layer of a positive-type photosensitive resin containing a compound on the substrate;
forming a pattern having the same shape as that of a channel by exposing the positive-type photosensitive resin layer;
forming a photosensitive layer, used to form the discharge port-forming member, over the pattern;
forming the discharge port by exposing the photosensitive layer to i-line; and
forming the channel, communicatively connected to the discharge port, by removing the pattern,
wherein the absorbance of the pattern measured at a wavelength of 365 nm in the thickness direction thereof is 0.2 or more and the compound is represented by the following formula: 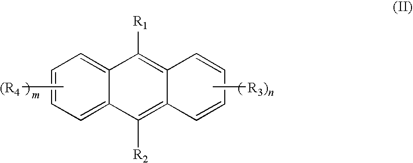
where R1, R2, R3, and R4 independently represent a hydrogen atom or a monovalent organic group and n and m independently represent an integer of zero to four.

9. The method according to claim 8, wherein the positive-type photosensitive resin is polymethyl isopropenyl ketone.

10. A method of manufacturing a liquid ejection head that includes a substrate including an energy-generating element generating energy used to discharge a liquid from a discharge port and also includes a discharge port-forming member having the discharge port, the method comprising the steps of:
forming a layer of a positive-type photosensitive resin containing a light absorbent on the substrate;
forming a pattern having the same shape as that of a channel by exposing the positive-type photosensitive resin layer;
forming a photosensitive layer, used to form the discharge port-forming member, over the pattern;
forming the discharge port by exposing the photosensitive layer to i-line; and
forming the channel by removing the pattern such that the channel is communicatively connected to the discharge port,
wherein the absorbance of the pattern measured at a wavelength of 365 nm in the thickness direction thereof is 0.2 or more and at least one of the ratio of the average molar absorption coefficient of the light absorbent at a wavelength of 230 to 260 nm to the molar absorption coefficient thereof at a wavelength of 365 nm and the ratio of the average molar absorption coefficient of the light absorbent at a wavelength of 280 to 330 nm to the molar absorption coefficient thereof at a wavelength of 365 nm is or less.
